(19) United States
(12) Patent Application Publication
(10) Pub. No.: US 2007/0183185 A1
(43) Pub. Date: Aug. 9, 2007

(54) FINFET-BASED SRAM WITH FEEDBACK

(75) Inventors: Zheng Guo, Berkeley, CA (US); Sriram Balasubramanian, Berkeley, CA (US); Radu Zlatanovici, Berkeley, CA (US); Tsu-Jae King, Fremont, CA (US); Borivoje Nikolic, Oakland, CA (US)

Correspondence Address: JOHN P. O'BANION;O'BANION & RITCHEY LLP, 400 CAPITOL MALL SUITE 1550, SACRAMENTO, CA, 95814, US

(73) Assignee: THE REGENTS OF THE UNIVERSITY OF CALIFORNIA, Oakland, CA (US)

(21) Appl. No.: 11/622,305

(22) Filed: Jan. 11, 2007

Related U.S. Application Data
(60) Provisional application No. 60/758,345, filed on Jan. 11, 2006.

(51) Int. Cl. G11C 11/00

(52) U.S. Cl. 365/156

(57) ABSTRACT

Intrinsic variations and challenging leakage control in current bulk-Si MOSFETs force undesired tradeoffs to be made and limit the scaling of SRAM circuits. Circuits and mechanisms are taught herein which improve leakage and noise margin in SRAM cells, such as those comprising either six-transistor (6-T) SRAM cell designs, or four-transistor (4-T) SRAM cell designs. The inventive SRAM cells utilize a feedback means coupling a portion of the storage node to a back-gate of an access transistor. Preferably feedback is coupled in this manner to both access transistors. SRAM cells designed with this built-in feedback achieve significant improvements in cell static noise margin (SNM) without area penalty. Use of the feedback scheme also results in the creation of a practical 4-T FinFET-based SRAM cell that achieves sub-100 pA per-cell standby current and offers similar improvements in SNM as the 6-T cell with feedback.

### CROSS-REFERENCE TO RELATED APPLICATIONS

This application claims priority from U.S. provisional application Ser. No. 60/758,345, filed on Jan. 11, 2006, incorporated herein by reference in its entirety.

### STATEMENT REGARDING FEDERALLY SPONSORED RESEARCH OR DEVELOPMENT

Not Applicable

### INCORPORATION-BY-REFERENCE OF MATERIAL SUBMITTED ON A COMPACT DISC

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. § 1.14.

A portion of the material in this patent document is also subject to protection under the maskwork registration laws of the United States and of other countries. The owner of the maskwork rights has no objection to the facsimile reproduction by anyone of the patent document or the patent disclosure, as it appears in the United States Patent and Trademark Office publicly available file or records, but otherwise reserves all maskwork rights whatsoever. The maskwork owner does not hereby waive any of its rights to have this patent document maintained in secrecy, including without limitation its rights pursuant to 37 C.F.R. § 1.14.

### BACKGROUND OF THE INVENTION

1. Field of the Invention

This invention pertains generally to memory devices, and more particularly to FinFET Static Random Access Memory (SRAM) devices.

2. Description of Related Art

Memory cells within integrated circuit devices, and in particular Static Random Access Memory (SRAM) arrays, occupy a large fraction of the chip area in many current designs. Looking toward the future, it appears that memory will continue to consume the same or even larger fractions of the chip real estate. To accommodate this need, scaling of memory density must continue to track the scaling trends of logic. Notably, however, increased transistor leakage and parameter variation present challenges for scaling of conventional six-transistor (6-T) SRAM cells. As Metal-Oxide Semiconductor Field-Effect Transistors (MOSFETs) are scaled down to the nanoscale regime, statistical dopant fluctuations, oxide thickness variations, and line-edge roughness increase the spread in transistor threshold voltage (Vₜ) and thus the on-current and off-current. In order to limit static power dissipation in large caches, lower supply voltage can be used; however, a low supply voltage coupled with large transistor variability compromises cell stability, measured as the static noise margin.

Accordingly, a need exists for an apparatus and method of increasing the stability and noise margin of static memory cells without adversely increasing leakage current or cell area. These needs and others are met within the present invention, which overcomes the deficiencies of previously developed static memory devices and methods.

### BRIEF SUMMARY OF THE INVENTION

According to one or more aspects of the invention, memory cell architectures are described which provide data retention in a stable manner with sufficient noise margins during standby, read access, and write access. Furthermore, the invention can provide reductions in leakage current and even reduce the area of the memory cell.

### DEFINITIONS

As an aid to understanding the various aspects of the present invention, certain terms used throughout the specification and claims are defined below. However, those skilled in the art will appreciate that the following definitions are provided solely for the purpose of convenience and not as a substitute for other recitations and uses within the specification and claims.

AXR, AXL—refers to an “Access Transistor” which is configured for accessing the data in a memory cell for reading and/or writing.

BG—refers to a “back-gate”, which is an additional gate coupled to the channel of a field effect transistor (FET), and typically on the surface of a “fin-type” FET (FinFET) device opposite a front-gate. The gate of a FinFET typically encircles the fin, wherein there is a first gate and a second gate which are not electrically isolated. A back-gate can be created on a FinFET by removing the gate material above the channel, leaving a separate front-gate and back-gate which are not in contact with one another except through the channel.

BL and BLC—refers to “bit-line” and “complementary bit-line”, respectively, and which are respectively connected to first and second data nodes of the memory data cell. These lines work in cooperation during writing, and typically the voltage differential developed between these sense lines is what leads to switching the state of the cell. BLC is also referred to as bit-line bar, wherein the term “bar” generally denotes a complementary or differential signal orientation.

NPD—refers to an “NMOS Pull-Down” device.

NR, NL, PR and PL—refer to “NMOS right”, “NMOS left”, “PMOS right” and “PMOS left” and designate NMOS pull-down transistors or PMOS load transistors accordingly.

SCE—refers to “Short-Channel Effects” which arise as channel length (1) approaches the same order of magnitude as depletion region thicknesses of source and drain junctions, or (2) is approximately equal to the source and drain junction depth. One prominent short channel effect is channel depletion region charge reduction.

SNM—refers to “Static Noise Margin” of a memory cell which represents the minimum DC-voltage disturbance necessary to upset cell state.

WL—refers to “Word Line” which is a signal coupled to the AXR and AXL (access transistors) of the memory cell and which goes active when data is to be read from or written into the cell.

According to an aspect of the invention, shortcomings of conventional transistor architectures are addressed by using a FinFET architecture which allows for controlling short channel effects with a thin body, wherein the drain saturation current can be increased while simultaneously reducing leakage currents. One embodiment comprises a six-transistor (6-T) SRAM memory cell. Another embodiment comprises a four-transistor (4-T) SRAM memory cell. Both embodiments employ multiple-gate FETs. Preferred embodiments of the invention utilize access transistors having a separate front-gate and back-gate, wherein the back-gate is connected to the data storage node to modulate the threshold of the access transistor and thus increase static noise margin. Beneficially, this novel feedback mechanism makes practical the fabrication of 4-T memory cells which can achieve sub-100 pA/cell standby currents.

In one embodiment, FinFET devices are configured as back-gated structures to dynamically adjust the strength of the devices. In this embodiment, two independent gates are created, such as along opposing surfaces of the body. The number of fins in the NMOS pull-down devices can be increased to increase the cell β-ratio to increase static noise margin. It will be appreciated that fins are typically added as discrete units, so a fin is either added or not added.

In one embodiment, NMOS pull-down devices (NPD) are laid-out incorporating a rotation to increase the read margin.

According to an aspect of the invention, a 4-T memory cell can be implemented using less chip area while maintaining data integrity with low leakage values. In one embodiment, the 4-T cell is configured with dynamic feedback, to selectively inject a retention current, I_{RETENTION}. The dynamic feedback provides for increasing the noise margin during read or write operations.

In one embodiment, a static random access memory (SRAM) device comprises: (a) a plurality of transistors forming a memory cell; (b) the memory cell having an access transistor; (c) a storage node within the memory cell for retaining binary data; (d) a back-gate on the access transistor; and (e) an electrical connection between the storage node and the back-gate of the access transistor. It should be appreciated that the back-gate is substantially electrically isolated from the front-gate of the access transistor.

In one embodiment, the access transistor comprises a fin-type field effect transistor (FinFET). The connection of the cell storage node to the back-gate of the access transistor provides dynamic feedback, such as for modulating (adjusting) transistor strength. The memory cell can be configured with a pull-down transistor coupled to the back-gate of the access transistor to provide transistor strength control, thus improving the read margin for the cell. In one implementation the memory cell comprises a six transistor (6-T) configuration while in another implementation a four transistor (4-T) configuration is taught. It should, however, be recognized that the techniques described can be applied to memory cells having any desired number of transistors.

In another embodiment, a static random access memory (SRAM) cell comprises: (a) an access transistor; (b) a storage node; (c) a back-gate on the access transistor; and (d) an electrical connection from the storage node to the back-gate of the access transistor.

Accordingly, as aspect of the invention is an improved static random access memory (SRAM) cell having an access transistor and a storage node. In one embodiment, the improvement comprises: (a) a back-gate on at least one of the access transistors; and (b) a connection between the access transistor back-gate and the storage node.

The invention provides numerous beneficial aspects for static memory cell designs a number of which are outlined below.

An aspect of the invention is to provide enhanced memory cell designs which retain data stability despite reduced cell geometries.

Another aspect of the invention is the coupling of the storage node within the memory cell to the back-gate of the access transistor.

Another aspect of the invention is coupling a signal to the back-gate of a FinFET access transistor to provide dynamic transistor threshold adjustment.

Another aspect of the invention is to provide memory cell designs which exhibit reduced leakage characteristics.

Another aspect of the invention is to provide memory cell designs which provide these enhancements over planar MOSFET SRAM cells.

Another aspect of the invention is to increase read margins to prevent data flipping during read operations.

Another aspect of the invention is the suppression of Short-channel effects (SCE) through the use of thin-body transistor structures.

Another aspect of the invention is the use of thin-body transistor structures without heavy doping.

Another aspect of the invention is the inclusion of FinFET transistors within a memory cell, such as within a six transistor (6-T) memory cell.

Another aspect of the invention is the use of FinFET transistors having a separate front-gate and back-gate to replace one or more of the access transistors.

Another aspect of the invention is the use of the back-gate of a FinFET transistor structure in both 6T and 4T memory cells to increase data stability.

Another aspect of the invention involves rotating portions of the channel and/or gate of the FinFET transistor to lie across two crystal orientations toward arriving at a wider read margin.

Another aspect of the invention is to provide a four transistor (4-T) SRAM memory cell configuration based on the use of back-gated FinFET transistors.

A still further aspect of the invention is the incorporation of sleep transistors within the 4-T SRAM memory cell to reduce leakage current.

Further aspects of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1A is a perspective view of a FinFET transistor.

FIG. 1B is a perspective view of a FinFET transistor with independent front-gate and back-gate structures.

FIG. 1C is a top view of a FinFET transistor with independent front-gate and back-gate structures.

FIG. 2A is a schematic circuit diagram of a 6-T SRAM cell. FIG. 2B is an exemplary cell layout for a FinFET-based 6-T SRAM cell.

FIG. 3 is an exemplary cell layout for a FinFET-based 6-T SRAM cell with rotated channel surface crystal orientation (100) access transistors.

FIG. 4 is a cell layout for a 6-T SRAM cell incorporating two-fin pull-down FETs according to an aspect of the present invention.

FIG. 5A shows butterfly plots for bulk-Si MOSFET-based 6-T SRAM cells.

FIG. 5B and 5C show butterfly plots for FinFET-based 6-T SRAM cells.

FIG. 5D is a plot of the noise margin obtained in response to the number of fins utilized in the NMOS pull-down devices.

FIG. 6A is a schematic circuit diagram of an SRAM cell having the storage node coupled to the back-gate of the access transistor according to an aspect of the present invention.

FIG. 6B is a cell layout of a 6-T SRAM cell with back-gate connections providing feedback according to an aspect of the present invention.

FIG. 7A is a butterfly plot for a FinFET 6-T SRAM cell having feedback according to an aspect of the present invention.

FIG. 7B is a plot of write margin and read margin according to an aspect of the present invention.

FIG. 8A is a schematic circuit diagram of a 4-T SRAM cell with back-gate connections according to an aspect of the present invention.

FIG. 8B is a cell layout of a 4-T SRAM cell with back-gate connections providing feedback according to an aspect of the present invention.

FIG. 9A is a butterfly plot for a 4-T SRAM cell with feedback compared during standby and reading according to an aspect of the present invention.

FIG. 9B is a plot of compensation current in response to access transistor back-gate voltage according to an aspect of the present invention.

FIG. 10A is a schematic circuit diagram of a column of 4-T SRAM cells having dynamic feedback according to an aspect of the present invention.

FIG. 10B is a plot of transient storage-node voltages during write access of the top 4-T SRAM cell of FIG. 10A.

FIG. 10C is a plot of transient storage-node voltages within a 4-T SRAM cell neighboring the accessed 4-T SRAM cell of FIG. 10A.

FIG. 11 is a plot of static noise margin distributions in response to described architectural variations for 4-T and 6-T SRAM cell variants.

FIG. 12A is a schematic of an SRAM cell sub-array into which sleep transistors have been incorporated according to an aspect of the present invention.

FIG. 12B is a butterfly plot for the 4-T SRAM cell with and without gated leakage reduction.

### DETAILED DESCRIPTION OF THE INVENTION

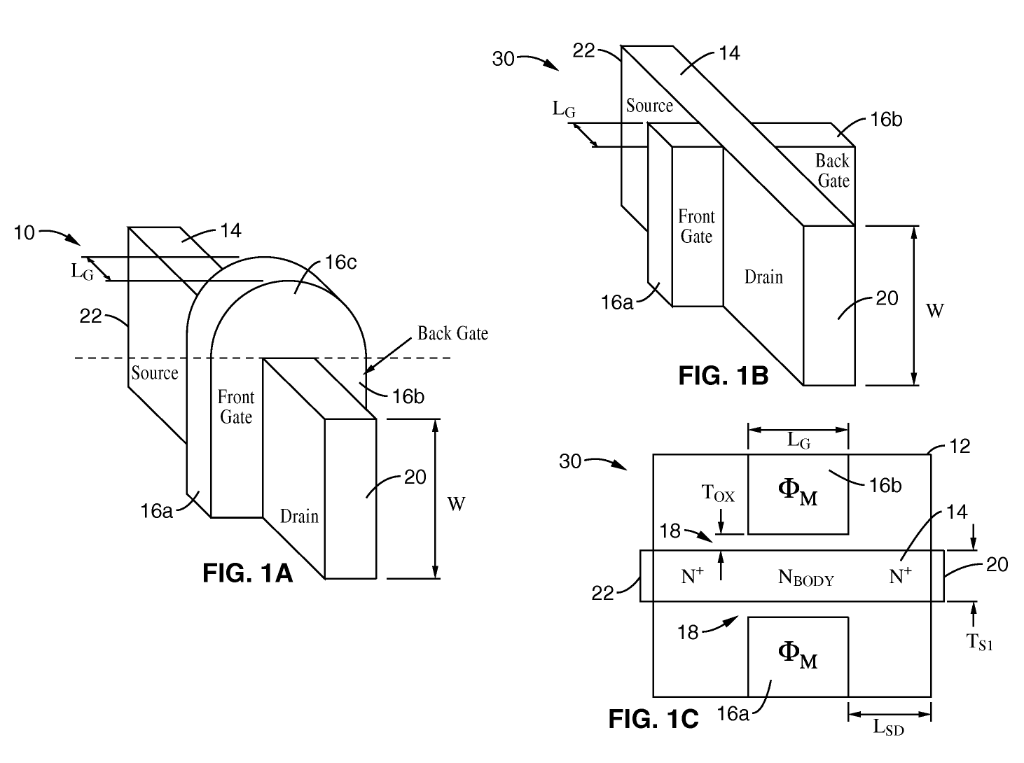

Referring more specifically to the drawings, for illustrative purposes the present invention is embodied in the apparatus generally shown in FIG. 1 through FIG. 12B. It will be appreciated that the various aspects, embodiments, modes and operations may vary without departing from the basic concepts as disclosed herein.

### FinFET Transistor Characteristics

The FinFET transistor structure has been developed as an alternative to the planar bulk-silicon (bulk-Si) MOSFET structure for improved gate-length scalability. FinFETs utilize a Si fin (rather than a planar Si surface) as the channel/body, and the gate electrode straddles the fin. The fin width is the effective body thickness, and the fin height is the effective channel width. In the “on” state, current flows between the source and drain along the gated sidewall surfaces of the Si fin. Short-channel effects (SCE) are suppressed by utilizing a thin body; namely, by making the fin very narrow so that its width is less than the channel length. Heavy channel doping is not required for SCE control, and hence can be eliminated to minimize variations due to statistical dopant fluctuation effects.

The gates on either side of the fin are adapted for being in electrical isolation to allow for independent operation by selectively removing the gate material in the region directly on top of the fin. In double-gate (DG) operating mode, the two gates are biased together to switch the FinFET on/off. By contrast, when configured in a back-gate (BG) operating mode the two gates are biased independently, with one gate used to switch the FinFET on/off and the other gate used to adjust the threshold voltage Vₜ. BG operation offers dynamic performance tunability which can be leveraged to improve trade-offs in SRAM design.

### 6-T SRAM Design Tradeoffs

Area Versus Yield:

The functionality and density of a memory array are its most important properties. Functionality is guaranteed for large memory arrays by providing sufficiently large design margins, which are determined by device sizing (channel widths and lengths), the supply voltage and, marginally, by the selection of transistor threshold voltages. Although up-sizing the transistors increases the noise margins, it increases the cell area and thus lowers the density.

Area Versus Yield; Hold Margin:

A six transistor (6-T) static RAM memory cell comprises two cross-coupled complementary metal-oxide-semiconductor (CMOS) inverters formed by the transistors PL, NL, PR, NR, and two access transistors AXL, AXR. In standby mode, the left PMOS load transistor (PL) must be strong enough to compensate for the sub-threshold and gate leakage currents of all the NMOS transistors connected to the storage node V_{L}. This is becoming more of a concern due to the dramatic increase in gate leakage and degradation in I_{ON}/I_{OFF} ratio in the most recent generations of technology. Coupled with the recent trend to decrease the cell supply voltage during standby to reduce static power consumption, this makes it increasingly more difficult to design robust low-power memory arrays.

Hold stability is commonly quantified by the cell static noise margin (SNM) in standby mode. The SNM of an SRAM cell represents the minimum DC-voltage disturbance necessary to upset the cell state, and can be quantified by the length of a side of the maximum sized square that can fit inside the butterfly curves formed by the cross-coupled inverters.

Area Versus Yield; Read Stability Margin:

During a read operation, the right storage node voltage V_{R} rises above 0V, to a voltage determined by the resistive voltage divider set up by the access transistor (AXR) and the right NMOS pull-down transistor (NR) between the bit line and right storage node. The ratio of the width/length of NR to AXR determines how high V_{R} will rise and is commonly referred to as the cell β-ratio. If V_{R} exceeds the trip point of the inverter formed by PL and NL, the cell bit will flip during the read operation, causing a read upset.

Read stability can also be quantified by the cell SNM during a read access. Since AXR operates in parallel to PR and keeps V_{R} from ever reaching 0V, the gain in the inverter transfer characteristic will decrease, causing a reduction in the separation between the butterfly curves and consequently a reduction in the SNM. For this reason, the cell is considered most vulnerable to noise during the read access. The read margin can be increased by up-sizing the pull-down transistor, which results in an area penalty and/or increasing the gate length of the access transistor, which increases the WL delay and reduces the write margin.

Area Versus Yield; Write Margin:

During a write operation, AXL and PL form a resistive voltage divider between the low-going bit-line complement and left storage node V_{L}. If the voltage divider pulls V_{L} below the trip point of the inverter formed by PR and NR, a successful write operation occurs. The write margin can be measured as the maximum BLC voltage that is able to flip the cell state while BL is kept high. The write margin can be improved by keeping the pull-up device at a minimum size and up-sizing the access transistor W/L at the cost of cell area and the cell read margin.

Area Versus Yield; Access Time:

During any read/write access, the WL is raised only for a limited amount of time as specified by the cell access time. If either the read or the write operation cannot be successfully carried out before the WL is lowered, access failure occurs.

A successful write access occurs when the voltage divider is able to pull V_{L} below the inverter trip point, after which the positive feedback in the cross-coupled inverters will cause the cell state to flip almost instantaneously. For the precharged bit-line architecture which employs voltage sensing amplifiers, a successful read access occurs if the pre-specified ΔV (required by the sense amplifier) between the bit-lines can be developed before the WL is discharged.

### Power Considerations

Large embedded SRAM arrays consume a significant portion of the overall power of an application processor. Power consumption in an SRAM array consists of short active periods and very long idle periods. For large arrays, standby power consumption is a major issue. Therefore, leakage reduction in large memory arrays has become essential for low-power VLSI applications. Cell leakage is commonly suppressed by either using longer channel lengths or higher transistor threshold voltages. Using longer channel lengths negatively impacts the cell area. In addition, the use of longer channel lengths tends to increase WL and BL capacitances, thus increasing access time and active power. Therefore, longer channel lengths are used sparingly, such as, for example, on the access transistors toward improving cell stability.

Utilizing higher transistor threshold voltages also negatively impacts the access time due to the lower read current; however, these higher thresholds improve read and write margins. While high threshold PMOS loads decrease the inverter trip point, high threshold NMOS pull-down devices (NPD) tend to increase it. Since the current driving ability of the NPD is larger than that of the PMOS load, increasing the threshold voltage of the NMOS transistors tends to have a stronger impact on the trip voltage, thus resulting in larger read and write margins. Typically, the maximum standby power of the memory array sets a lower limit (e.g., 0.4-0.5V) for the Vₜ in a given process. The margins in this case are maintained by setting the supply voltage sufficiently high.

Circuit techniques can be used to reduce memory leakage as well, such as, for example, using sleep transistors and body biasing. However, these reduce density and in some cases can compromise stability.

### Challenges for Scaling Bulk-Si SRAM

While it is possible to scale the classical bulk-Si MOSFET structure down into the sub-20 nm regime, SCE control requires heavy channel doping (>10¹⁸ cm⁻³) and heavy super-halo implants to control sub-surface leakage currents. As a result, carrier mobilities are severely degraded due to impurity scattering and a high transverse electric field in the on state. Furthermore, the increased depletion charge density results in a larger depletion capacitance hence a larger sub-threshold slope. Thus, for a given off-state leakage current specification, on-state drive current is degraded. Off-state leakage current is enhanced due to band-to-band tunneling between the body and drain. Vₜ variability caused by random dopant fluctuations is another concern for nanoscale bulk-Si MOSFETs.

The control of critical dimensions within a cell does not track as the scale of the cell is reduced, consequently the ratio of the standard deviation over the average increases. Successful implementation of large arrays requires design for five or more standard deviations. In view of the increasing variation as the design scales down, it becomes difficult to guarantee cell stability for large arrays of near-minimum-sized cells incorporated within low-power embedded applications. Increasing transistor sizes, on the other hand, is counter to the fundamental reason for scaling in the first place; namely, to increase density. Access time is dependent on wire delays and column height. To enhance the speed of memory cell arrays, segmentation is commonly employed. With further reductions in bit-line height, the overhead area of sense amplifiers becomes substantial.

### SRAM Cell Layout Aspects

Conventional SRAM cells have relatively high aspect ratios (AR); that is, the ratio of BL-parallel height to BL-orthogonal width. Recently, SRAM cells have been designed with a much smaller AR to allow for straight poly-Si gate lines and active regions. This cell design allows for very precise critical-dimension control, thereby reducing gate-length variations and corner-rounding issues as well as relaxing back-end design rules, making it highly manufacturable. Shorter cells along with the more relaxed metal pitch in this design result in a significant reduction in BL capacitance. The accompanying increase in the WL capacitance can be mitigated by the use of WL segmentation.

### Understanding Memory Cell Stability

The present invention is configured to provide for retaining data during standby mode despite reduced cell geometries. Obtaining this benefit generally requires that PMOS load devices must be of sufficient capacity to compensate for all the leakage paths from the “1” storage node. It will be recognized that data integrity (retaining data) during a read operation is a primary consideration within a memory device. During a read operation the “0” storage node rises to a value that is determined by the voltage division between the access transistor and the pull-down transistor. This value is typically referred to as the cell read voltage. If that value, however, exceeds the trip voltage of the inverter on the other side, the cell will change state (flip) causing a read upset. In typical situations the read margin is substantially less than the standby noise margin (SNM), in response to activation of the access transistor which degrades the gain of the voltage transfer curves (VTC). Accordingly, read margin is typically considered one of the most important constraints on design. As cell geometry is reduced, the variations in cell read voltage and trip voltage continue to increase, leading to unstable cells. Write margins must also be dealt with when scaling down memory cells. Write margin within the cell is taken as the highest bit-line (BL) voltage under which we can still write to the cell when bit-line bar (BLC) is kept pre-charged. The present invention provides mechanisms for dealing with these and other problems.

### Understanding Short-Channel Effects

Short-channel effects (SCE) are another issue that must be dealt with in designing memory devices. Suppression of sub-surface leakage by using high channel doping and heavy halo implants degrades carrier mobility and thus the drain saturation current I_{dsat}, and also degrades sub-threshold swing. In addition, the use of thinner gate dielectrics to suppress SCE results in higher gate leakage. As geometries are reduced, Vₜ scattering due to random dopant fluctuations become more significant.

It can be seen that bulk-Si transistors are subject to a number of problems, so that new transistor architectures are sought to overcome these issues. One manner of reducing these effects, such as in response to dopant fluctuation, is to lightly dope the channels. A lightly doped channel gives rise to lower transverse electric field in the on state and negligible impurity scattering, hence higher carrier mobilities. SCE can be effectively suppressed by using a thin-body transistor structure such as the FinFET which allows for gate-length scaling down to the 10-nm regime without the use of heavy channel/body doping.

### Benefits of FinFET Architecture

The use of FinFET devices in the present invention allows for controlling short channel effects via a thin body/channel, therein simultaneously achieving higher I_{dsat} and lower leakage.

A lightly doped channel also allows FinFET devices to have negligible depletion charge and capacitance, which yields a steep sub-threshold slope. In addition, FinFETs have lower parasitic device capacitance because both depletion and junction capacitances are effectively eliminated, thereby reducing the BL capacitive load. In addition, the elimination of heavy doping in the channel minimizes Vₜ variations due to statistical dopant fluctuation effects. Therefore, FinFET-based SRAM cells are expected to show enhanced performance over bulk-Si MOSFET SRAM cells. Furthermore, FinFET devices can be operated according to the present invention as back-gated devices, such as by etching away that portion of the gate that extends over the fin, between the front-gate and the back-gate. Upon electrically isolating the front-gate from the back-gate, the back-gate of the device becomes available for modulating the strength of the device.

### EXAMPLE 1

### FinFET Design and Modeling

FIG. 1A through FIG. 1C illustrate views (perspective and top) of FinFET transistor embodiments 10 with a double-gated structure, and 30 adapted with a back-gate structure.

In the embodiment 10 of FIG. 1A, a fin body 14 is shown making up the transistor channel. A gate 16 overlays the fin, and includes a first side portion 16a, a second side portion 16b and a top portion 16c (above the body of the fin). It should be noted that the gate is shown in a vertical fin configuration which can be of similar dimension to the fin body of the channel. This configuration, having gates on both sides of the channel but which are not electrically separate from one another, is generally referred to as a double-gated FinFET.

In FIG. 1B, the top gate portion 16c of FIG. 1A has been removed to create the FinFET embodiment 30 configured with separate (i.e., substantially electrically isolated) front-gate 16a and back-gate 16b. FIG. 1C illustrates a top view of the back-gated FinFET upon substrate 12 having a lightly doped channel body 14. Front-gate 16a and back-gate 16b are coupled to fin body 14 through an insulating layer 18. On the ends of fin body 14 are shown source contact 20 and drain contact 22. Table 1 summarizes key design parameters for an embodiment of the FinFET.

FinFETs fabricated on wafers having a standard crystal orientation (001) have channels on the fin sidewalls that are oriented along (110) planes, for standard layouts. To capture the effect of fin-sidewall surface orientation on FinFET performance, the carrier mobilities were calibrated using experimental data for the (110) surface.

EXAMPLE 2

### Double-Gated (DG) FinFET SRAM Cell Designs

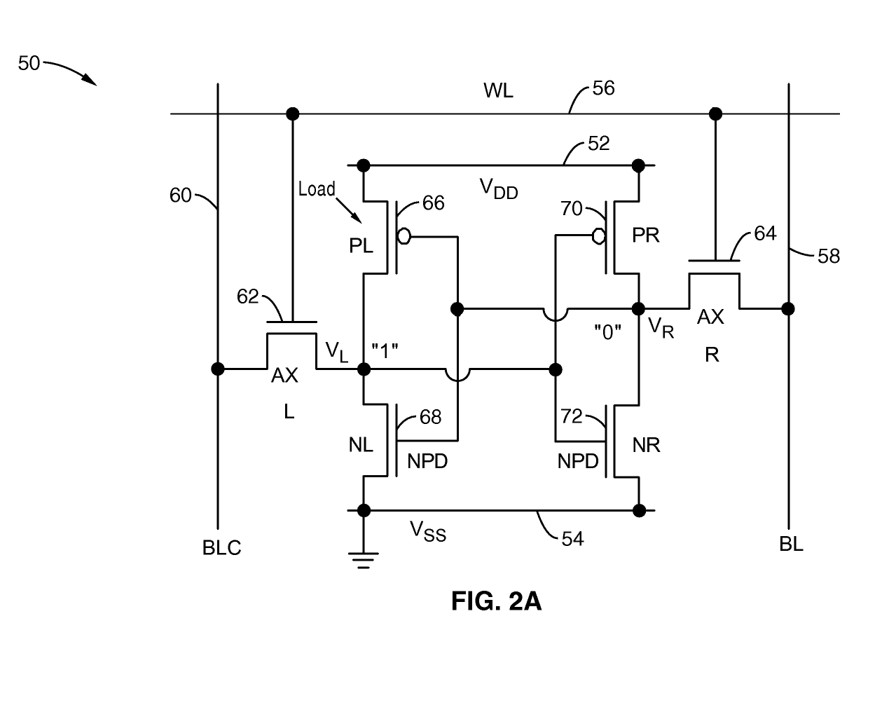

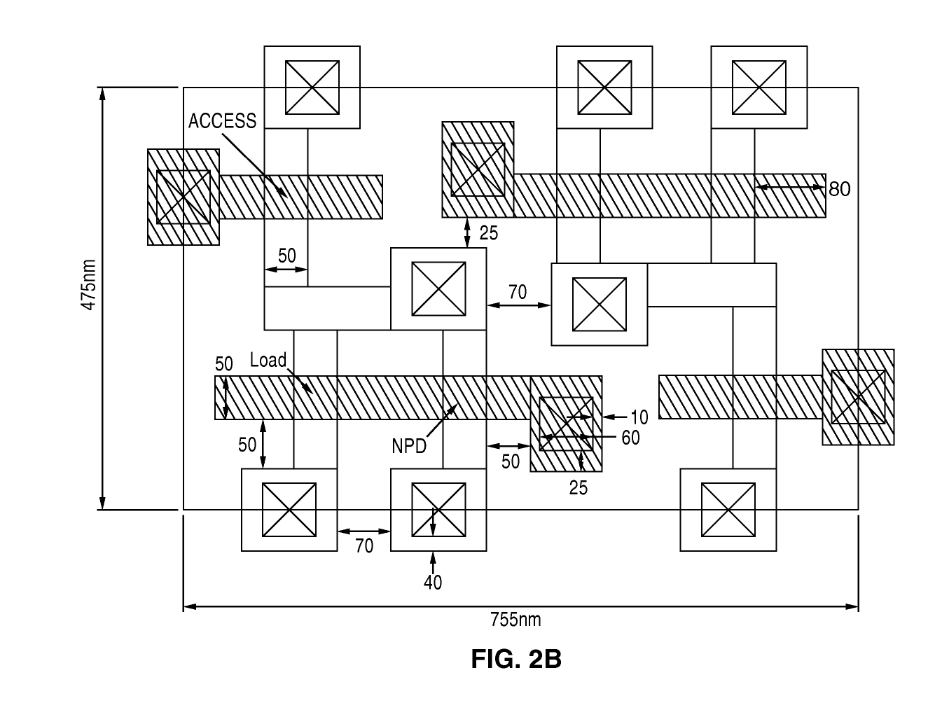

In comparison with bulk-Si MOSFET based SRAM cell architectures, the read margin can be improved by increasing the strength of the pull-down transistor relative to the access transistor, either by increasing the size-ratio between NR and AXR, such as shown in FIG. 2A, or enhancing carrier mobility in the pull-down devices.

FIG. 2A illustrates a schematic of an embodiment 50 of a double-gated (DG) static memory cell design. Power supply is represented as V_{DD} 52 and Vₛₛ 54. Signals are represented with a word line 56, bit-line 58, and bit-line complement 60. A first access transistor 62 is coupled to a first storage node of the memory cell and a second access transistor 64 is coupled to a second storage node of the memory cell. The four transistors which form the cross-coupled inverter latch of the memory cell comprise transistors 66, 68 on a first side, and transistors 70, 72 on a second side. FIG. 2B illustrates an example layout of the schematic of FIG. 2A, in which the open areas represent fin body areas and the cross hatched areas represent gate regions.

By way of example and not limitation, the layout was generated using a linearly scaled version of 90 nm node logic design rules, and with the dashed outline indicating the memory cell boundary. It should be appreciated that one of ordinary skill in the art can apply the teachings herein whenever beneficial to the scale and specific layout considerations of the given memory circuit. The layout of FIG. 2B, as with all layouts depicted herein, are shown dimensioned in nanometers (e.g., FIG. 2B, 3, 4, 6B and 8B) and the dimensions shown therein should not be confused with component reference numbers. Accordingly, it should be appreciated that the circuits and methods described herein can be implemented at any desired scale, and with variations in the configuration and organization of the FinFET devices, gating, and interconnects.

Electron mobility along (100) crystal planes in silicon is known to be higher than along (110) crystal planes. In order to increase the effective cell β-ratio and thus improve the cell read margin, the NMOS pull-down devices (NPD) can be rotated to have channel surface along the (100) crystal plane.

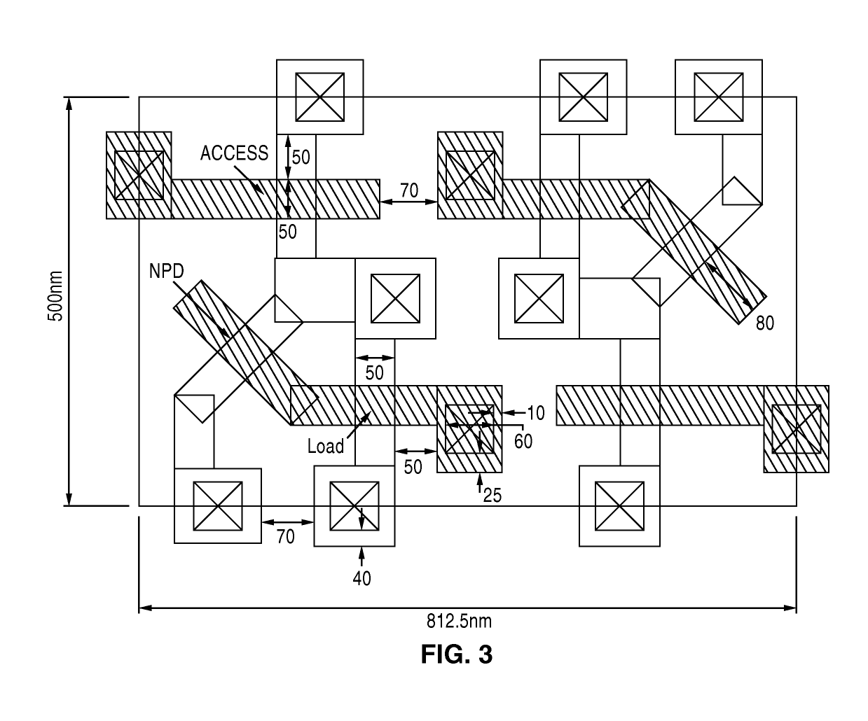

FIG. 3 illustrates another FinFET-based SRAM cell embodiment. Cell designs in planar bulk-Si CMOS are restricted in their orientations due to the spacing required to prevent interaction between the elements. However, in developing the present invention it has been recognized that the vertical nature of these FinFET designs substantially eliminates these forms of interaction at the surface of the die. One aspect of the invention provides fabricating FinFET-based SRAM cells containing transistors with channel surface both along (110) and (100) crystal planes by rotating the fins by 45° for the (100) fins as shown in the layout. Although not complex, printing rotated fins may be slightly more challenging with regard to lithography and could give rise to a minor increase in process variation.

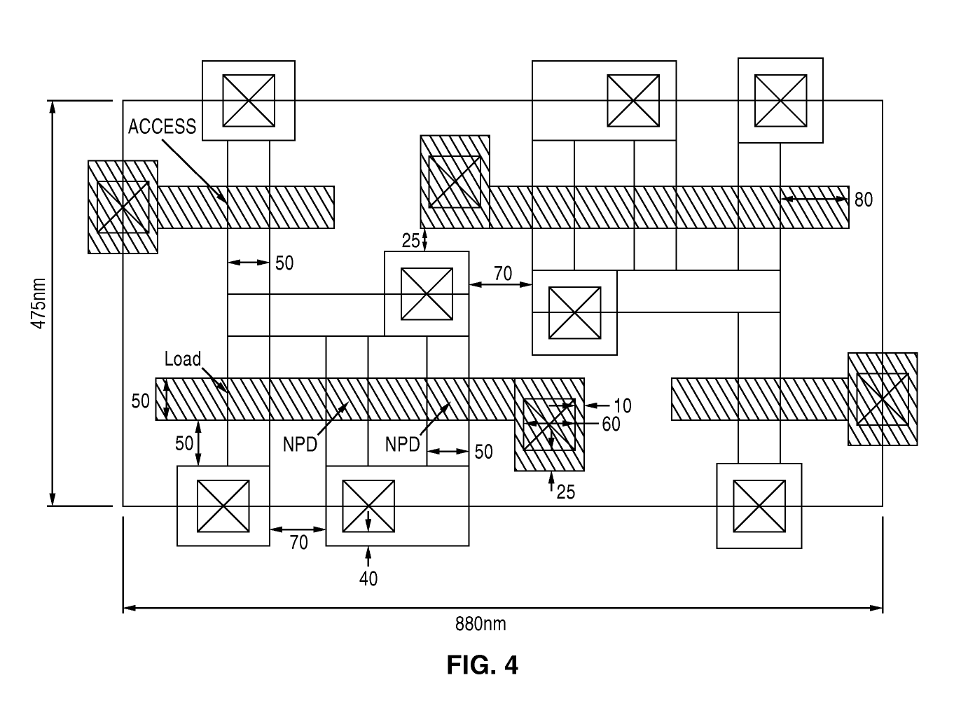

FIG. 4 illustrates an embodiment of a memory cell in which the size of the pull-down transistor, or the length of AXR, has been increased, toward substantially improving the obtainable read margin. Since the channel widths of FinFET devices are determined by the number of fins, only discrete sizing is available. Increasing the access device length has less impact on cell area but increases the WL capacitance and also negatively impacts the read current, resulting in slower access time.

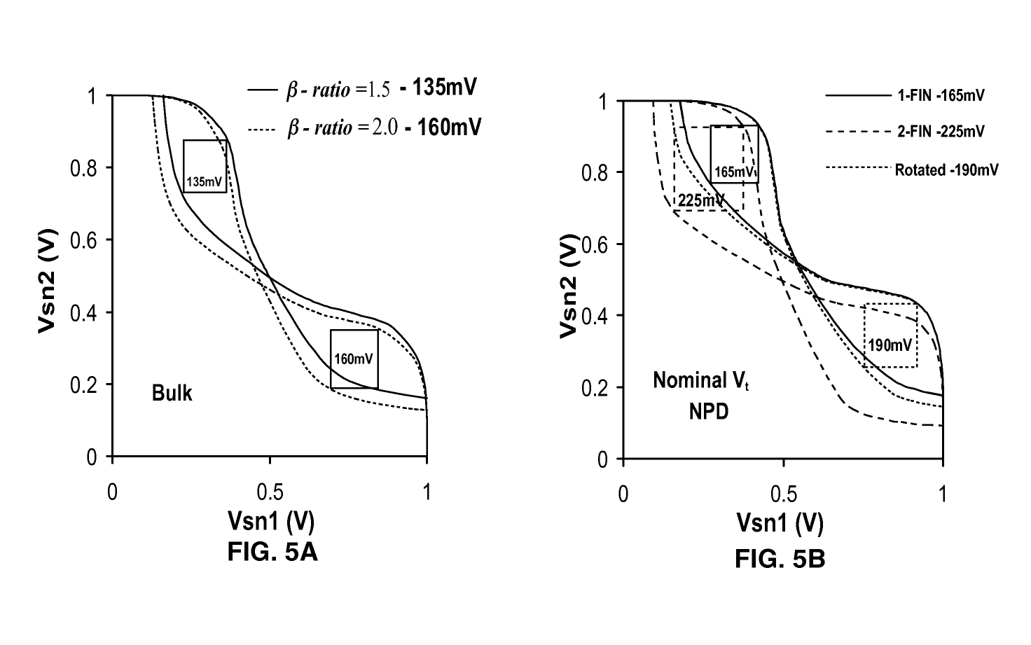

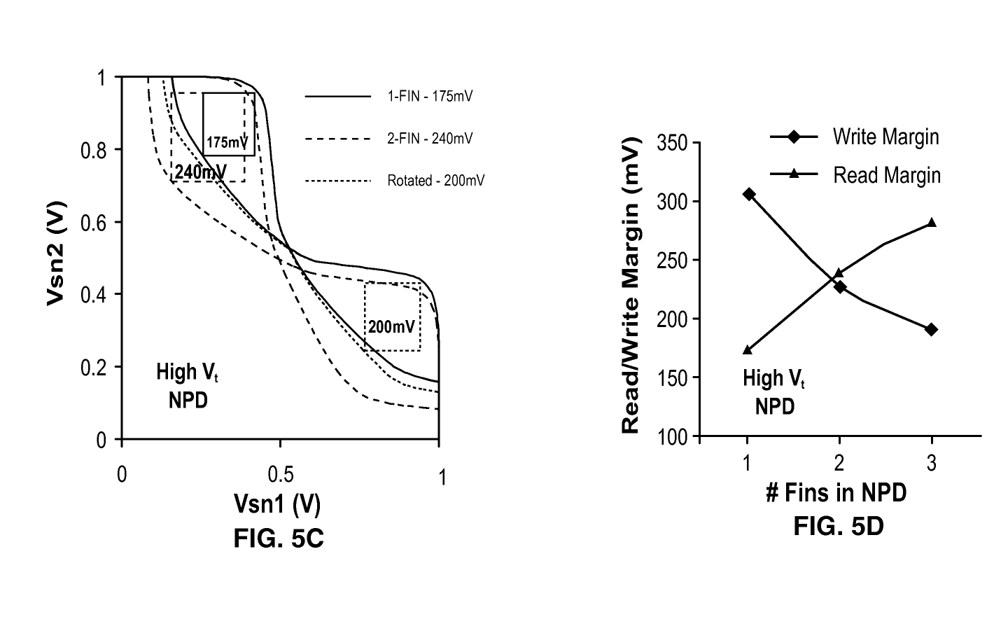

FIG. 5 shows how the read and hold margins are raised for both the 6-T bulk-Si MOSFET-based SRAM cell and the 6-T FinFET-based SRAM cell (simulated using device parameters from Table 1). It should be appreciated that hold stability is represented as cell static noise margin which is often quantified by the length of the side of the largest square which can be fit between the curves produced by the cross-coupled inverters. As shown, the DG 6-T FinFET-based SRAM with one fin achieves a 22% improvement in the read SNM compared to its bulk-Si-based counterpart with β-ratio of 1.5. Moreover, a 15% further improvement in the read SNM, with a 13.3% area penalty, can be achieved by rotating the pull-down transistor. A 36% further improvement in the read SNM, with 16.6% area penalty, can be achieved by up-sizing the pull-down transistor by one fin.

In one implementation, higher threshold pull-down devices are used in the FinFET designs, by raising the gate work function of the NMOS and PMOS devices (both to 4.75 eV), to suppress leakage and to improve read/write margin. In addition, it should be appreciated that using a common gate work function improves manufacturability. The resulting improvements in SNM are shown in FIG. 5C. By contrast, it should be recognized that a higher Vₜ bulk-Si device might not translate to lower leakage due to band-to-band tunneling.

Whenever the pull-down devices are strengthened, either by adding fins or by rotating the access devices, the cell write margin is reduced. This reduction in write margin is primarily due to the reduction in the write trip voltage. The effect on the read and write noise margins in response to inserting extra fins is summarized in FIG. 5D.

### EXAMPLE 3

### Back-Gated (BG) FinFET 6-T SRAM Cell Designs

Whereas adaptive body biasing becomes less effective with bulk-Si MOSFET scaling, back-gate biasing of a thin-body MOSFET remains effective for dynamic control of Vₜ with transistor scaling, and can provide improved control of short-channel effects as well. The strong back-gate biasing effect can thus be leveraged to optimize the performance of FinFET-based SRAMs through a dynamic adjustment of the effective cell β-ratio.

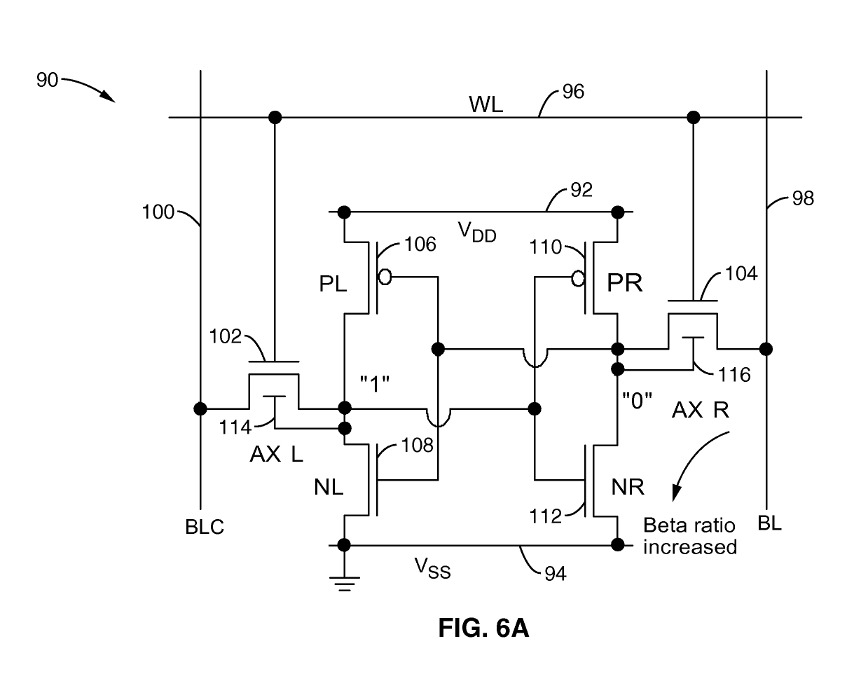

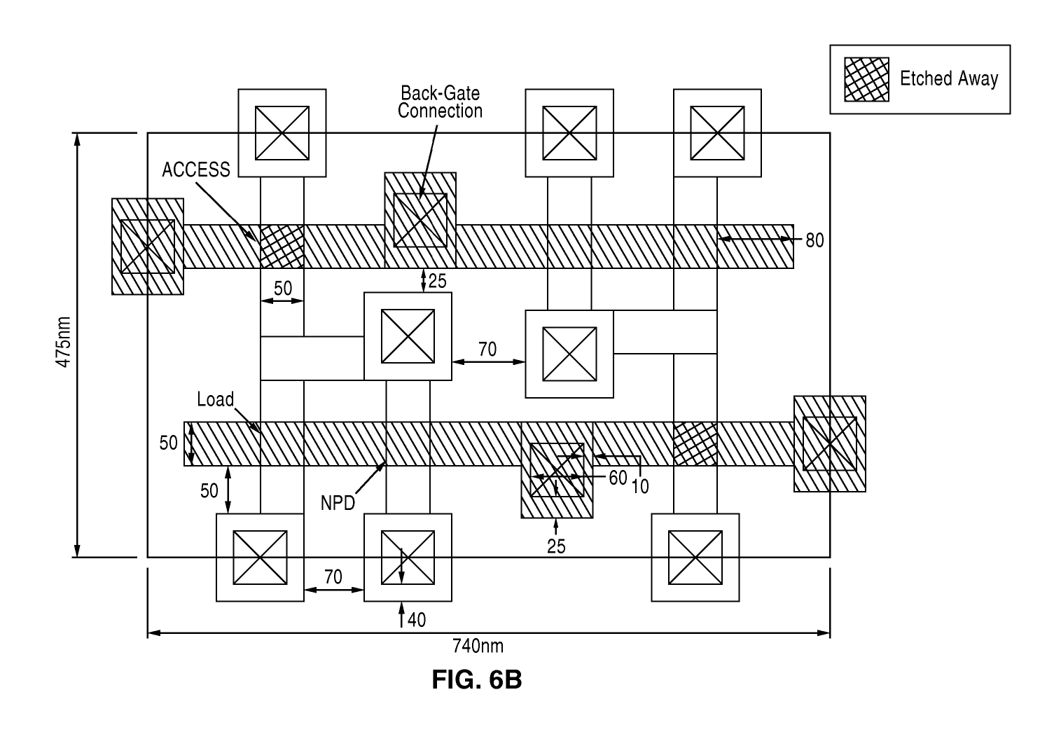

FIG. 6A illustrates an embodiment 90 of an SRAM memory cell. The power supply is represented as V_{DD} 92 and Vₛₛ 94. Signals are represented with a word line 96, bit-line 98, and bit-line complement 100. A first access transistor 102 is on a first side of the memory cell, and a second access transistor 104 is on a second side of the memory cell. The four transistors which form the cross-coupled inverter latch of the memory cell thus comprise transistors 106, 108 on the first side, and transistors 110, 112 on the second side.

In this embodiment each storage node of the memory cell is coupled to the back-gate of its access transistor so that the strength of the access transistor can be selectively decreased within the memory cell. It can be seen that a connection 114 is made between a first storage node and the back-gate of the first access transistor 102, while a connection 116 is made between a second storage node and the back-gate of the second access transistor 104.

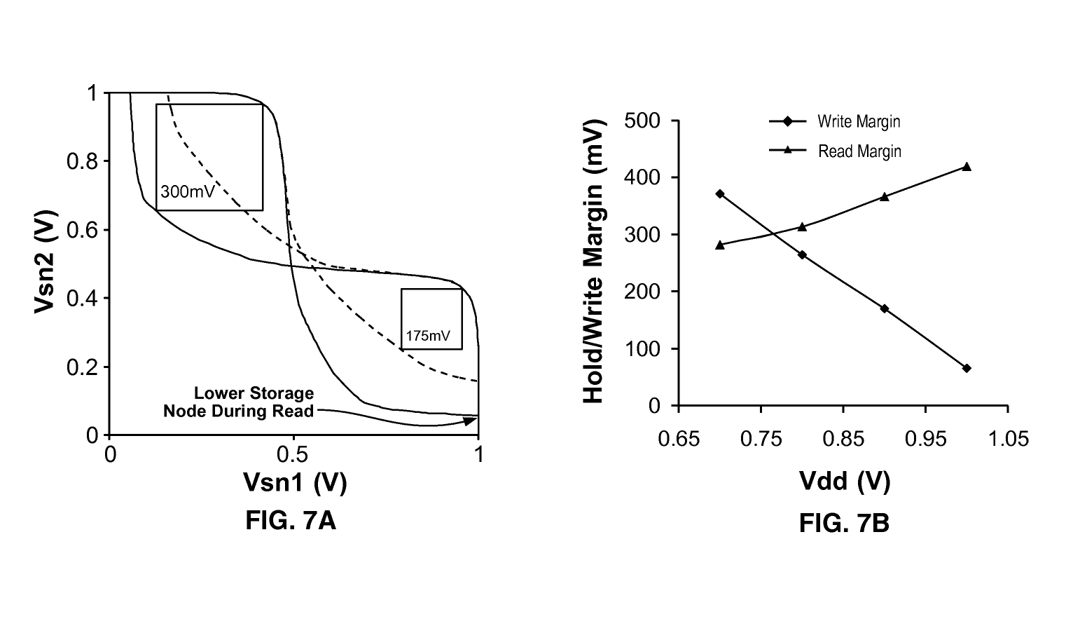

For example, if the stored bit is a “0”, the back-gate of the second access transistor 104 is biased at 0V, decreasing its strength. This effectively increases the β-ratio during the read cycle and thus improves the read margin. Although the BG access transistor has weaker current driving strength compared to the DG access transistor, the “0” storage node in the 6-T cell design with feedback stays closer to Vₛₛ than the conventional DG design (FIG. 7A); thus giving the BG access transistors in the 6-T cell design with feedback more gate overdrive. Therefore, introduction of the feedback provides a substantial read margin improvement over the DG design as seen by the butterfly plot of FIG. 7A. Moreover, this simple back-gate connection, exemplified by the layout of FIG. 6B, incurs no area penalty over a DG 6-T SRAM cell design. The cell area is actually reduced by 2% due to the disappearance of the 80 nm gate-poly extension over active (fin) that the DG access device required. A first back-gate connection can be seen in the upper center of the memory cell shown in FIG. 6B, while the etched away areas denote removal of gate material over the channel fin to isolate the front-gate and back-gate.

The main drawback of the 6-T SRAM design with feedback is the reduced write margin because of the reduction in the driving current of the BG access transistor at the “1” storage node as it is pulled low. The problem with reduced write margin can be partially overcome, without major impact on read SNM, by adjusting the strength of the PMOS load devices. The PMOS load devices can be made weaker by either adjusting their threshold voltage or gate length. However, each of these techniques provides only a limited write margin improvement.

FIG. 7B is a plot summarizing a write margin enhancement that can be attained in response to reduced cell supply and the corresponding impact on the hold SNM. A significant improvement in the write margin can be attained by lowering the cell supply voltage during write. This is made possible by adopting the long aspect ratio cell layout, since the cell supply can be routed vertically for each column and can be exploited to break the contention between read and write optimization. With the ability for column based biasing, cell supply voltage can be selectively lowered only for the column containing the cell under write access. This keeps the cell stability high for all other cells connected to the same WL. Thus, high read-margins and write-margins can be independently achieved. Essentially, the contention between read-margin and write-margins has been replaced by a contention between hold-margins and write-margins, thereby offering a substantially increased optimization window. FIG. 7B summarizes aspects of the enhanced operation.

### EXAMPLE 4

### 4-T SRAM Cell with Dynamic Feedback

Toward providing further reductions in cell area, aspects of the invention include embodiments of 4-T SRAM cell designs. In conventional attempts to create a 4-T SRAM cell design, high-leakage PMOS access transistors are used to compensate for the leakage currents in the pull-down NMOS transistors during standby. Although compensation current is only needed for the “1” storage node, both PMOS access transistors draw currents from the bit-lines, resulting in high power dissipation. Dynamic control of the PMOS threshold voltage (Vₜₚ) according to the present invention offers a means for selectively adjusting the compensation leakage current, and also provides higher effective β-ratio for the 4-T SRAM cell design, thereby making the manufacture of 4-T SRAM cells practical for a number of application areas.

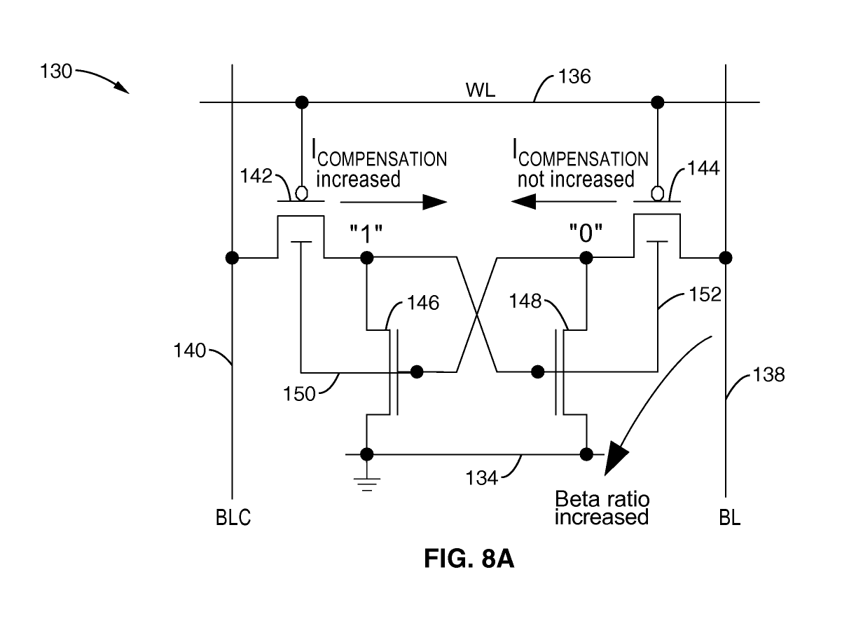

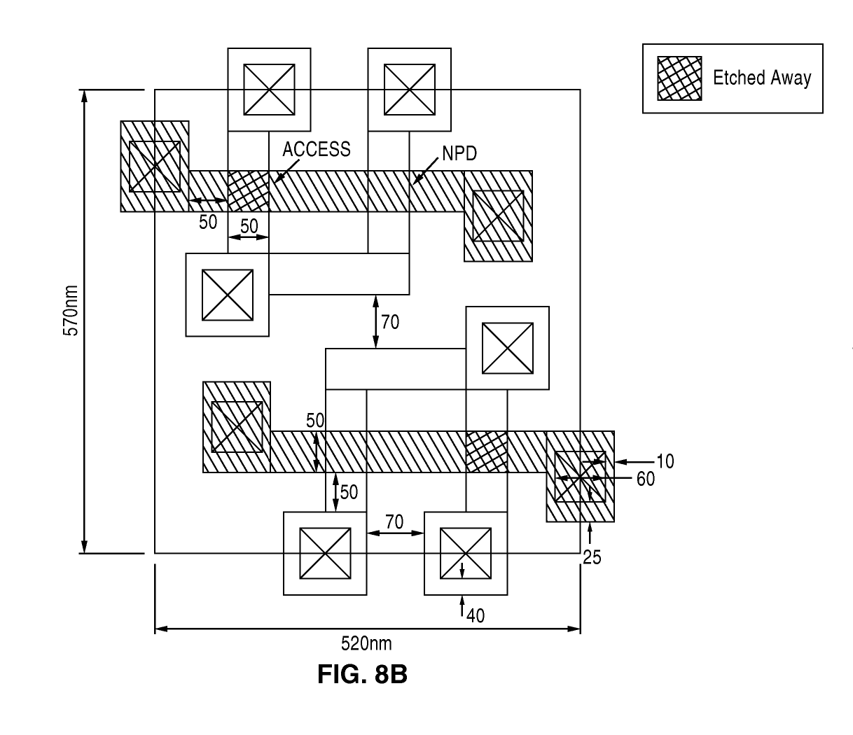

FIG. 8A and FIG. 8B illustrate an embodiment 130 of a four transistor (4-T) SRAM memory cell. Power is shown as Vₛₛ 134, while V_{DD} is supplied through the access transistors. Signals are represented with a word line 136, bit-line 138, and bit-line complement 140. A first access transistor 142 is on the left side, and a second access transistor 144 is on the right side.

In this embodiment the storage node is coupled to the back-gate of the opposite access transistor. Specifically, it can be seen that a connection 150 is made between the back-gate of the left access transistor 142 and the right storage node, while a connection 152 is made between the back-gate of the right access transistor 144 and the left storage node.

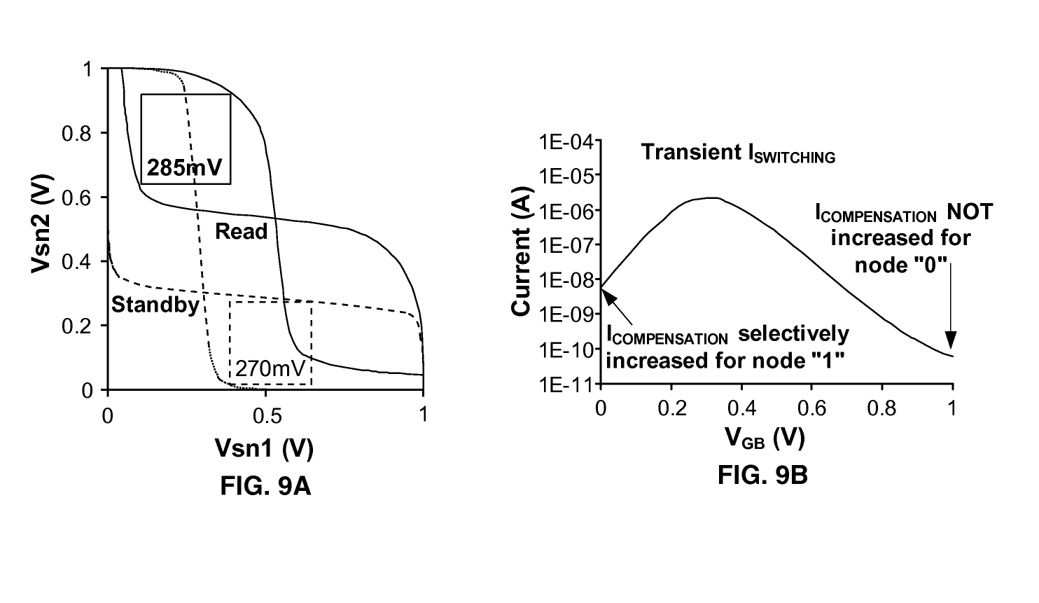

By cross-coupling the storage node to the back-gate of the access transistor on the opposite side, as shown in FIG. 8A high compensation current can be selectively injected only into the “1” storage node as seen in FIG. 8A. In addition, the β-ratio is increased because the access transistor connected to the “0” storage node is made weaker with its back-gate biased by the “1” storage node. It should be noted that a “1” back-gate bias lowers the PMOS drive current. The resulting improvement in read margin is shown in FIG. 9A. FIG. 9B shows how the compensation current varies with the access-transistor back-gate voltage. Compared to the DG 6-T cell design presented earlier, the 4-T cell design with feedback achieves a 63% improvement in read margin as well as a 17.4% area savings.

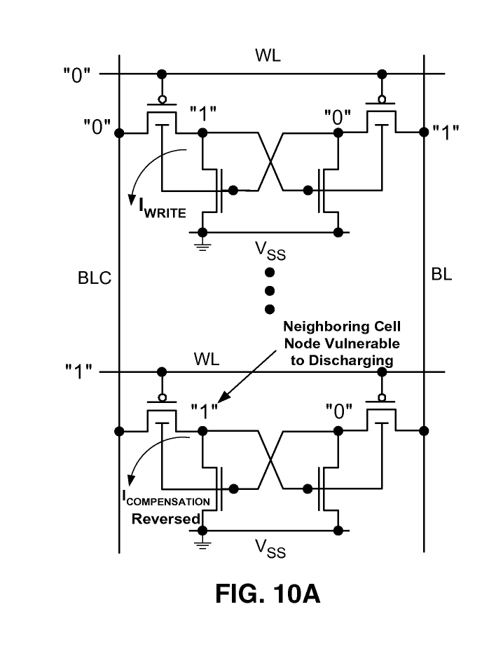

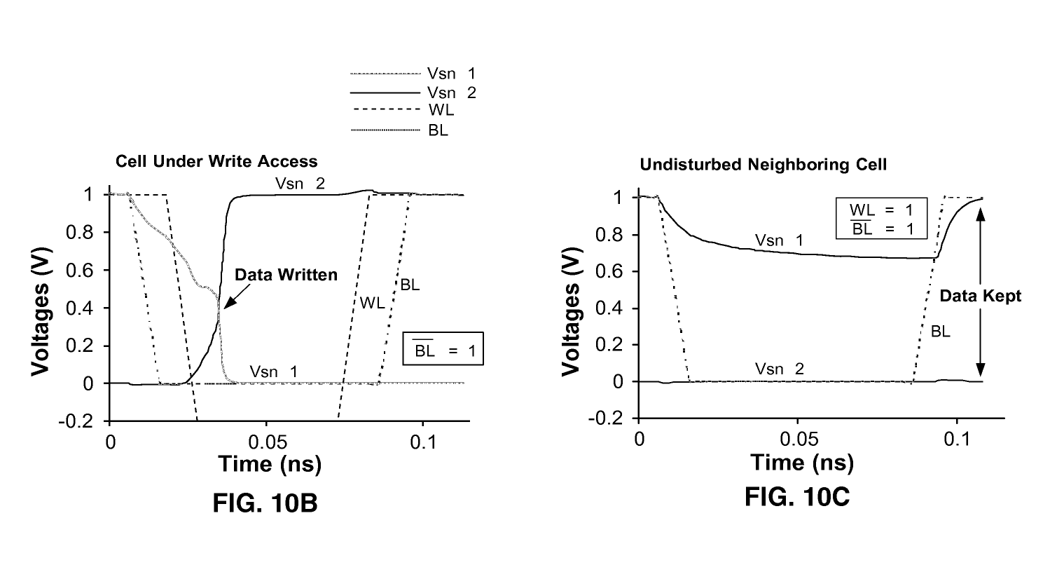

An issue for the conventional 4-T SRAM cell design is the possibility of a bit-flip while a neighboring cell (sharing the same bit-line) is being written More specifically, when the bit-lines are set according to the data to be written, the directions of the compensation currents can be reversed in the cells connected to the same bit-lines, potentially flipping those cells and causing a neighboring cell write upset (FIG. 10A). This issue can be addressed by noting that the PMOS devices can only pull a “1” storage node down to |Vₜₚ|; thus, the state of the cell is not flipped if |Vₜₚ| is higher than the NMOS threshold voltage, Vₜₙ. If this is the case, the storage node voltages will be restored when the bit-lines are recharged after a successful write operation. Since dynamic compensation is employed, high leakage, low-Vₜₚ, PMOS access devices are not needed for standby stability. Therefore, neighboring cell write upset can be alleviated by employing high-Vₜₚ PMOS and low-Vₜₙ NMOS devices, as illustrated in FIG. 10B and FIG. 10C which show the storage node voltage transients for a cell under write access and a neighboring cell, respectively. Since high-Vₜₚ PMOS devices tend to be relatively weak, PMOS drive current should be increased to improve the write margin. This can be done by using a negative word-line bias voltage.

### Process-Induced Variations

Process-induced variations in device parameters (for example gate length, fin width) cause Vₜ variations resulting in spread in SRAM SNM distributions.

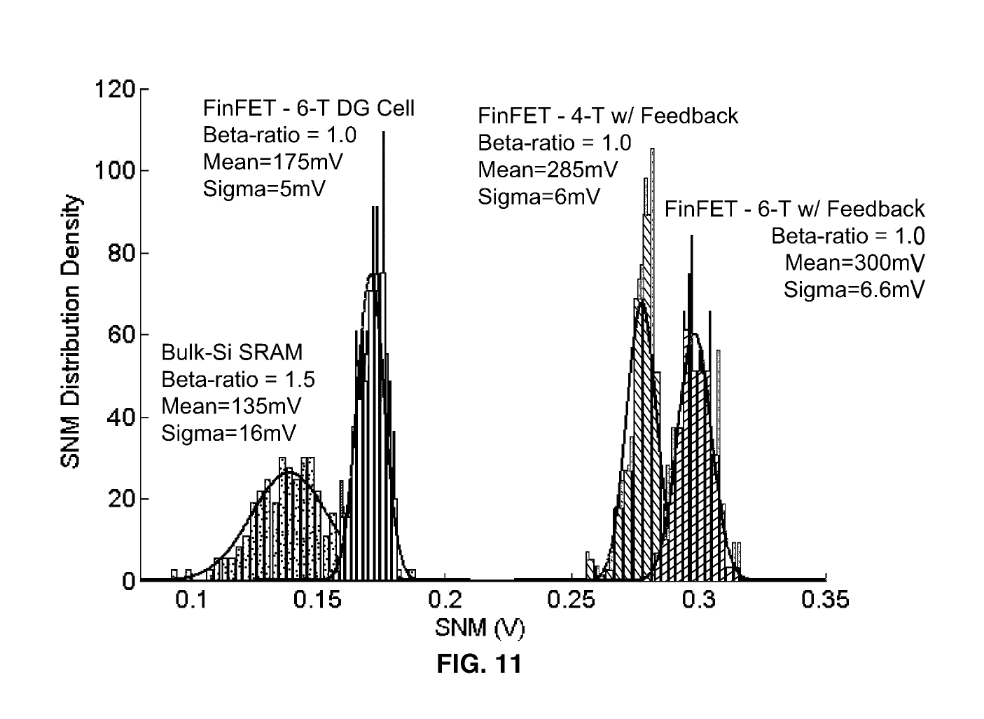

FIG. 11 illustrates by way of example the impact of statistical process variations on static noise margin (SNM) for FinFET-based and bulk-Si MOSFET-based SRAM cells, obtained using mixed-mode simulations.

### Array Design Issues

### Sleep-Mode

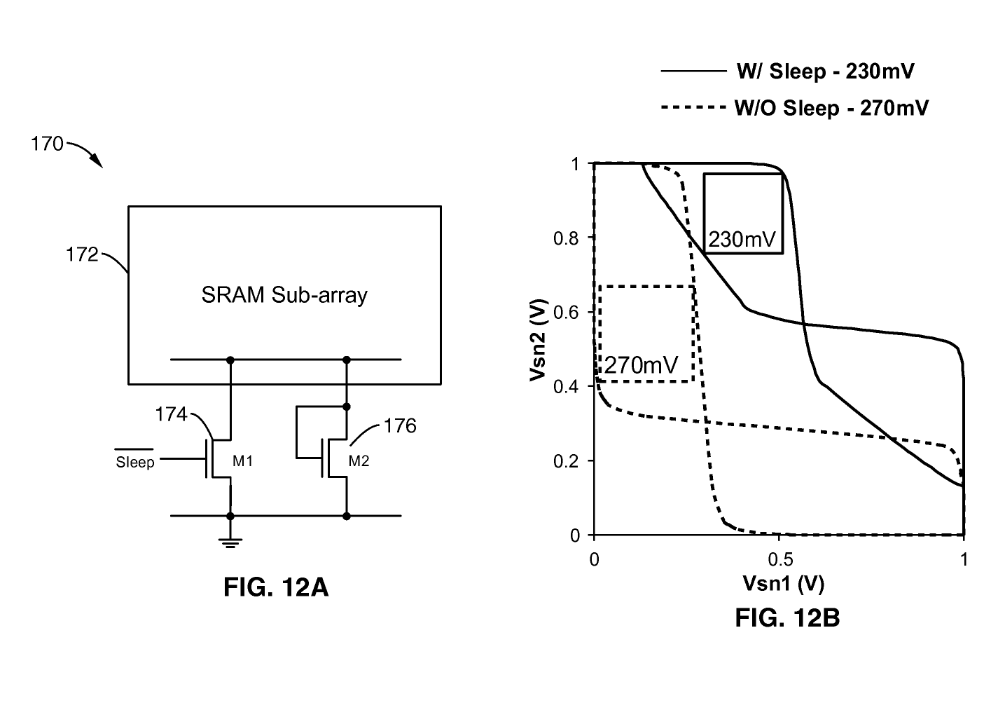

FIG. 12A illustrates an embodiment 170 in which the state (on/off) of NMOS sleep transistors coupled to the memory sub-array are modulated in response to the mode of operation (standby or active) of the SRAM sub-array 172. During standby, transistor M1 174 is turned off and the gated Vₛₛ is boosted by the Vₜₙ of the diode-connected transistor M2 176.

FIG. 12B shows the impact of this leakage reduction scheme on the standby SNM. It is observed that the sleep transistors do incur a minor impact on cell standby SNM, such as for example less than about 15% degradation. The simulated cell standby currents for the 4-T and the 6-T FinFET-based designs are summarized in Table 2. The FinFET cell design according to the invention requires less chip area than a cell implemented with bulk-Si MOSFETs, because it can do away with the N-well to P-well spacing, and in addition does not require four metal contacts inside the cell. It should be appreciated that with the present techniques, 6-T FinFET-based SRAM cells can achieve less than 0.2 nA/cell of standby current just by using high Vₜ devices, and that the leakage of 4-T FinFET-based SRAM cells can be kept under 80 pA/cell by utilizing sleep transistors while sustaining a 230 mV standby SNM, for V_{dd}=1V.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

TABLE 1
Device Parameters Used For Taurus Simulations

| Parameters | FinFET | Bulk-Si |
|---|---|---|
| L_{G} (nm) | 22 | 22 |
| L_{SD} (nm) | 24 | 24 |
| Tₒₓ (Å) | 11 | 11 |
| T_{Si} (nm) | 15 | — |
| V_{DD} (V) | 1.0 | 1.0 |
| Channel Doping, N_{BODY} (cm⁻³) | 10¹⁶ | 4 × 10¹⁸ |
| H_{FIN} (nm) | 30 | — |
| S/D doping gradient (nm/dec) | 4 | 4 |

TABLE 2
Summary Of Bulk And FinFET SRAM Characteristics

| | Cell Area | Static Noise | |
|---|---|---|---|
| Cell Design | (μm²) | Margin (mV) | I_{cell, standby} (nA) |
| 6-T DG w/1-FIN NPD | 0.36 | 175 | 0.191 |
| (high Vₜ) | | | |
| 6-T DG w/2-FIN NPD | 0.42 | 240 | 0.26 |
| (high Vₜ) | | | |
| 6-T DG w/Rotated NPD | 0.41 | 200 | 0.191 |
| (high Vₜ) | | | |
| 6-T w/Feedback (high Vₜ) | 0.35 | 300 | 0.193 |
| 4-T w/o Gated V_{SS} | 0.30 | 285 | 5.9 |
| 4-T w/Gated V_{SS} | 0.30* | 285 | 0.076 |

*There is a per column area overhead for this implementation

What is claimed is:

1. A static random access memory (SRAM) device, comprising:
a plurality of transistors forming a memory cell;
said memory cell having an access transistor;
said memory cell having a storage node;
said access transistor having a back-gate;
said storage node connected to the back-gate of the access transistor.

2. An SRAM device as recited in claim 1, wherein said access transistor comprises a fin-type field effect transistor (FinFET).

3. An SRAM device as recited in claim 1, wherein connection of said storage node to said back-gate provides for dynamic feedback.

4. An SRAM device as recited in claim 3, wherein said dynamic feedback provides for dynamic transistor strength adjustment.

5. An SRAM device as recited in claim 4:
wherein said memory cell further comprises a pull-down transistor; and
wherein said transistor strength adjustment provides for decreasing access transistor strength.

6. An SRAM device as recited in claim 5, wherein decreasing access transistor strength improves read margin.

7. An SRAM device as recited in claim 3, wherein said dynamic feedback provides for dynamic transistor leakage adjustment.

8. An SRAM device as recited in claim 7:
wherein said memory cell further comprises a pull-down transistor; and
wherein said transistor leakage adjustment provides for decreasing access transistor leakage.

9. An SRAM device as recited in claim 8, wherein decreasing access transistor leakage reduces power consumption.

10. An SRAM device as recited in claim 1, wherein said memory cell comprises a four transistor (4-T) configuration.

11. An SRAM device as recited in claim 1, wherein said memory cell comprises a six transistor (6-T) configuration.

12. A static random access memory (SRAM) cell, comprising:
an access transistor;
a storage node;
said access transistor having a back-gate;
said storage node connected to the back-gate of the access transistor.

13. An SRAM cell as recited in claim 12, wherein said access transistor comprises a fin-type field effect transistor (FinFET).

14. An SRAM cell as recited in claim 12, wherein connection of said storage node to said back-gate provides for dynamic feedback.

15. An SRAM cell as recited in claim 14, wherein said dynamic feedback provides for dynamic transistor strength adjustment.

16. An SRAM cell as recited in claim 15:
wherein said memory cell further comprises a pull-down transistor; and
wherein said transistor strength adjustment provides for decreasing access transistor strength.

17. An SRAM cell as recited in claim 16, wherein decreasing access transistor strength improves read margin.

18. An SRAM device as recited in claim 14, wherein said dynamic feedback provides for dynamic transistor leakage adjustment.

19. An SRAM device as recited in claim 18:
wherein said memory cell further comprises a pull-down transistor; and
wherein said transistor leakage adjustment provides for decreasing access transistor leakage.

20. An SRAM device as recited in claim 19, wherein decreasing access transistor leakage reduces power consumption.

21. An SRAM cell as recited in claim 12, wherein said memory cell comprises a four transistor (4-T) configuration.

22. An SRAM cell as recited in claim 12, wherein said memory cell comprises a six transistor (6-T) configuration.

23. In a static random access memory (SRAM) cell having an access transistor and a storage node, the improvement comprising:
said access transistor having a back-gate connected to said storage node.

24. An improved SRAM cell as recited in claim 23, wherein said access transistor comprises a fin-type field effect transistor (FinFET).

25. An improved SRAM cell as recited in claim 23, wherein connection of said storage node to said back-gate provides for dynamic feedback.

26. An improved SRAM cell as recited in claim 25, wherein said dynamic feedback provides for dynamic transistor strength adjustment.

27. An improved SRAM cell as recited in claim 26:
wherein said memory cell further comprises a pull-down transistor; and
wherein said transistor strength adjustment provides for decreasing access transistor strength.

28. An improved SRAM cell as recited in claim 27, wherein decreasing access transistor strength improves read margin.

29. An SRAM device as recited in claim 25, wherein said dynamic feedback provides for dynamic transistor leakage adjustment.

30. An SRAM device as recited in claim 29:
wherein said memory cell further comprises a pull-down transistor; and
wherein said transistor leakage adjustment provides for decreasing access transistor leakage.

31. An SRAM device as recited in claim 30, wherein decreasing access transistor leakage reduces power consumption.

32. An improved SRAM cell as recited in claim 23, wherein said memory cell comprises a four transistor (4-T) configuration.

33. An improved SRAM cell as recited in claim 23, wherein said memory cell comprises a six transistor (6-T) configuration.
